(19) United States
(12) Patent Application Publication
(10) Pub. No.: US 2025/0311101 A1
(43) Pub. Date: Oct. 2, 2025

(54) WIRING SUBSTRATE

(71) Applicant: IBIDEN CO., LTD., Ogaki (JP)

(72) Inventor: Kazuki KAJIHARA, Ogaki (JP)

(73) Assignee: IBIDEN CO., LTD., Ogaki (JP)

(21) Appl. No.: 19/088,014

(22) Filed: Mar. 24, 2025

(30) Foreign Application Priority Data
Mar. 26, 2024 (JP) 2024-048915

(51) Int. Cl. H05K 1/11; H05K 1/03

(52) U.S. Cl. CPC H05K 1/112; H05K 1/0306; H05K 2201/0175

(57) ABSTRACT

A wiring substrate includes a core substrate including a resin substrate, a glass substrate in opening of the resin substate, and filling resin between the resin and glass substrates, and a build-up part on the core substrate and including conductor layers and resin insulating layers. The glass substrate has first through-hole conductors including main material including copper, the resin substrate has second through-hole conductors including main material including copper, and the first and second through-hole conductors are formed in the glass and resin substrates respectively such that density of the first through-hole conductors is greater than density of the second through-hole conductors, where the density of the first through-hole conductors is number of the first through-hole conductors per unit area of surface of the glass substrate, and the density of the second through-hole conductors is number of the second through-hole conductors per unit area of surface of the resin substrate.

### CROSS-REFERENCE TO RELATED APPLICATIONS

The present application is based upon and claims the benefit of priority to Japanese Patent Application No. 2024-048915, filed Mar. 26, 2024, the entire contents of which are incorporated herein by reference.

### BACKGROUND OF THE INVENTION

### Field of the Invention

The present invention relates to a wiring substrate.

### Description of Background Art

Japanese Patent Application Laid-Open Publication No. 2014-127701 describes a wiring board having a core layer. The entire contents of this publication are incorporated herein by reference.

### SUMMARY OF THE INVENTION

According to one aspect of the present invention, a wiring substrate includes a core substrate including a resin substrate having an opening, a glass substrate positioned in the opening of the resin substate, and a filling resin filling a gap between the resin substrate and the glass substrate, and a build-up part formed on the core substrate and including conductor layers and resin insulating layers such that the conductor layers and the resin insulating layers are alternately laminated. The glass substrate of the core substrate has first through-hole conductors including a main material including copper, the resin substrate of the core substrate has second through-hole conductors including a main material including copper, and the first through-hole conductors and the second through-hole conductors are formed in the glass substrate and the resin substrate respectively such that a density of the first through-hole conductors is greater than a density of the second through-hole conductors, where the density of the first through-hole conductors is a number of the first through-hole conductors per unit area of a surface of the glass substrate, and the density of the second through-hole conductors is a number of the second through-hole conductors per unit area of a surface of the resin substrate.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a wiring substrate according to an embodiment of the present invention;

FIG. 2 is an enlarged cross-sectional view schematically illustrating a part of a wiring substrate according to an embodiment of the present invention; and

FIG. 3 is an enlarged cross-sectional view schematically illustrating a part of a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

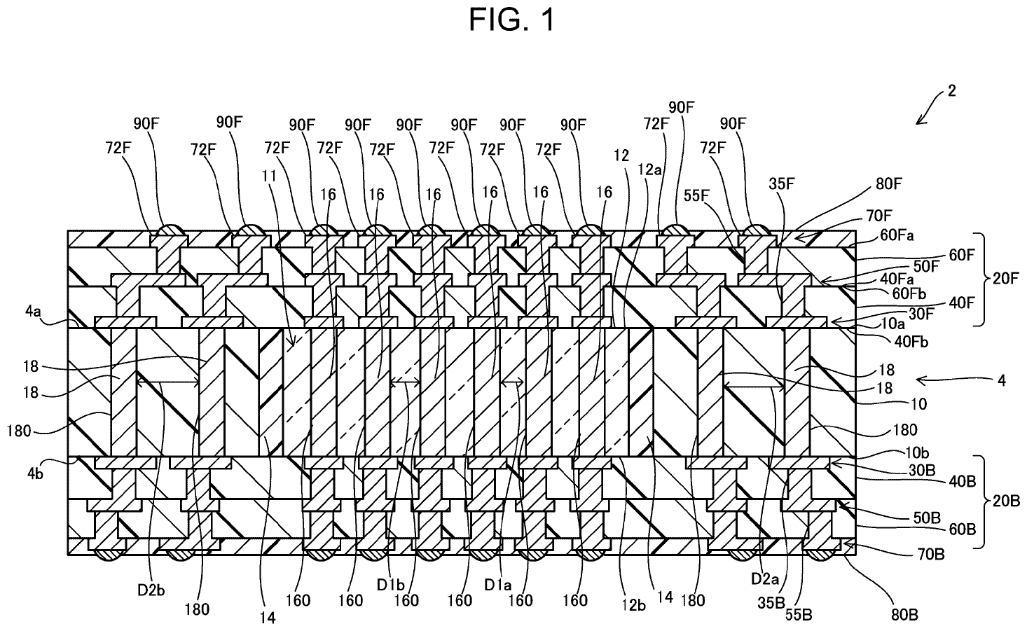

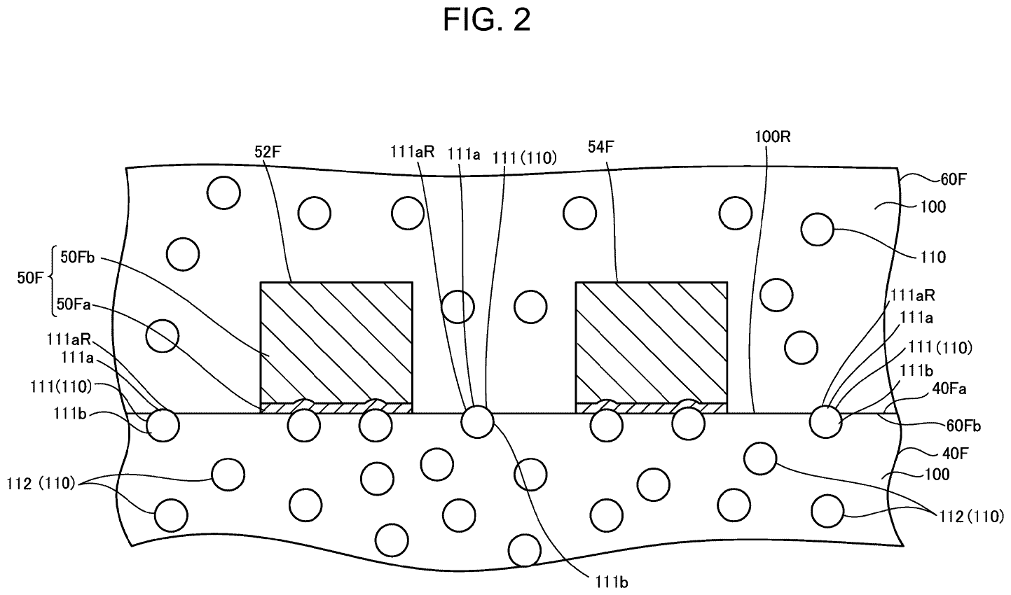

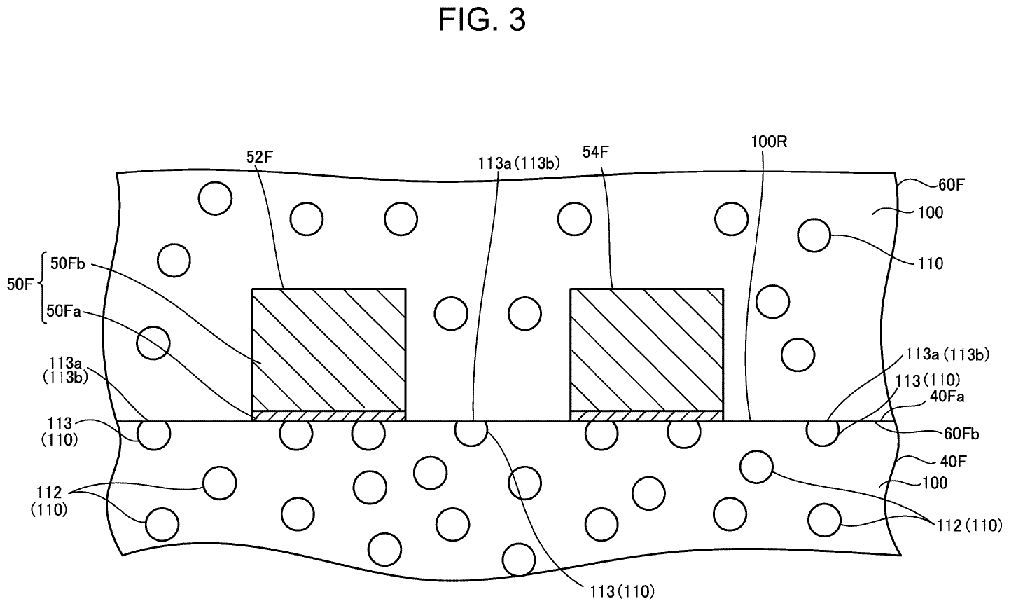

FIG. 1 is a cross-sectional view illustrating a wiring substrate 2 according to an embodiment of the present invention. FIGS. 2 and 3 are each an enlarged cross-sectional view illustrating a part of the wiring substrate 2 of the embodiment. As illustrated in FIG. 1, the wiring substrate 2 includes a core substrate 4, a first build-up part (20F), a second build-up part (20B), solder resist layers (80F, 80B), and bonding members (90F).

The core substrate 4, which has a ninth surface (4a) and a tenth surface (4b) on the opposite side with respect to the ninth surface (4a), includes a resin substrate 10, a glass substrate 12, and a filling resin 14. The resin substrate 10 has a first surface (10a), a second surface (10b) on the opposite side with respect to the first surface (10a), and an opening 11 extending from the first surface (10a) to the second surface (10b). The ninth surface (4a) and the first surface (10a) form a substantially common surface, and the tenth surface (4b) and the second surface (10b) form a substantially common surface. The resin substrate 10 is formed of a resin. An example of the resin is an epoxy resin. The resin substrate 10 may contain inorganic particles such as silica particles. The resin substrate 10 may contain a reinforcing material such as a glass cloth. The opening 11 has a substantially rectangular planar shape. The glass substrate 12 is arranged in the opening 11. The glass substrate 12 has a third surface (12a) and a fourth surface (12b) on the opposite side with respect to the third surface (12a). The third surface (12a) and the first surface (10a) form a substantially common surface. The fourth surface (12b) and the second surface (10b) form a substantially common surface. The glass substrate 12 is formed of glass. The filling resin 14 fills a gap between the resin substrate 10 and the glass substrate 12. An example of the filling resin 14 is an epoxy resin. The filling resin 14 may contain inorganic particles such as silica particles.

The glass substrate 12 has multiple first through holes 160 and multiple first through-hole conductors 16 extending from the third surface (12a) to the fourth surface (12b). The first through-hole conductors 16 are respectively formed in the first through holes 160. The resin substrate 10 has multiple second through holes 180 and multiple second through-hole conductors 18 extending from the first surface (10a) to the second surface (10b). The second through-hole conductors 18 are respectively formed in the second through holes 180. A primary material of the first through-hole conductors 16 and the second through-hole conductors 18 is copper. A density of the first through-hole conductors 16 is greater than a density of the second through-hole conductors 18. The density of the first through-hole conductors 16 is the number of first through-hole conductors 16 per unit area of the third surface (12a). The density of the second through-hole conductors 18 is the number of second through-hole conductors 18 per unit area of the first surface (10a). For example, the density of the first through-hole conductors 16 can be calculated by dividing the total number of the first through-hole conductors 16 by the area of the third surface (12a). An area of each of the first through holes 160 is included in the area of the third surface (12a). For example, the density of the second through-hole conductors 18 can be calculated by dividing the total number of the second through-hole conductors 18 by the area of the first surface (10a). An area of each of the second through holes 180 is included in the area of the first surface (10a).

A minimum spacing (D1a) between adjacent first through-hole conductors 16 is smaller than a minimum spacing (D2a) between adjacent second through-hole conductors 18. A maximum spacing (D1b) between adjacent first through-hole conductors 16 is smaller than a maximum spacing (D2b) between adjacent second through-hole conductors 18. The maximum spacing (D1b) between adjacent first through-hole conductors 16 is smaller than the minimum spacing (D2a) between adjacent second through-hole conductors 18.

The first build-up part (20F) is formed on the ninth surface (4a) of the core substrate 4. The first build-up part (20F) has multiple conductor layers (30F, 50F, 70F) and multiple resin insulating layers (40F, 60F). The conductor layers (30F, 50F, 70F) and the resin insulating layers (40F, 60F) are alternately laminated. The first build-up part (20F) has via conductors (35F) that connect the conductor layers (30F, 50F) and via conductors (55F) that connect the conductor layers (50F, 70F).

The conductor layer (30F) is formed on the ninth surface (4a) of the core substrate 4. The conductor layer (30F) includes a conductor circuit on the first surface (10a) of the resin substrate 10 and a conductor circuit on the third surface (12a) of the glass substrate 12. The conductor layer (30F) is mainly formed of copper. The conductor circuit on the first surface (10a) of the resin substrate 10 includes a conductor circuit connected to upper ends of the second through-hole conductors 18. The conductor circuit on the third surface (12a) of the glass substrate 12 includes a conductor circuit connected to upper ends of the first through-hole conductors 16. The conductor layer (30F) can include a conductor circuit on the filling resin 14 for connecting the conductor circuit on the first surface (10a) of the resin substrate 10 and the conductor circuit on the third surface (12a) of the glass substrate 12. Alternatively, the conductor layer (30F) does not have a conductor circuit on the filling resin 14 for connecting the conductor circuit on the first surface (10a) of the resin substrate 10 and the conductor circuit on the third surface (12a) of the glass substrate 12.

The resin insulating layer (40F) is formed on the conductor layer (30F) and the ninth surface (4a). The resin insulating layer (40F) has a fifth surface (40Fa) and a sixth surface (40Fb) on the opposite side with respect to the fifth surface (40Fa). The sixth surface (40Fb) is closer to the first surface (10a) than the fifth surface (40Fa). As illustrated in FIG. 2, the resin insulating layer (40F) is formed of a resin 100 and a large number of inorganic particles 110 dispersed in the resin 100. The resin 100 is an epoxy-based resin. An example of the resin is a thermosetting resin. The inorganic particles 110 are glass particles. It is also possible that the inorganic particles 110 are alumina particles. A content of the inorganic particles 110 in the resin insulating layer (40F) is 75 wt % or more.

The inorganic particles 110 can include first inorganic particles 111 that are partially embedded in the resin 100 and second inorganic particles 112 that are embedded in resin 100. The second inorganic particles 112 are completely embedded in the resin 100. The first inorganic particles 111 and the second inorganic particles 112 have spherical shapes. The first inorganic particles 111 are each formed of a first portion (111a) protruding from the resin 100 and a second portion (111b) embedded in the resin 100. The fifth surface (40Fa) of the resin insulating layer (40F) is formed of an upper surface (100R) of the resin 100 and exposed surfaces (111aR) of the first portions (111a) exposed from the upper surface (100R).

A ratio (R) of a volume of the first portions (111a) to a volume of the first inorganic particles 111 ((the volume of the first portions (111a))/(the volume of the first inorganic particles 111)) is greater than 0 and less than or equal to 0.4. The ratio (R) is preferably 0.2 or less. The ratio (R) is more preferably 0.1 or less. The ratio (R) is most preferably 0.05 or less. The upper surface (100R) of the resin 100 forming the fifth surface (40Fa) of resin insulating layer (40F) is substantially flat. The upper surface (100R) of the resin 100 has substantially no recesses. Therefore, the fifth surface (40Fa) has substantially no recesses. The fifth surface (40Fa) has an arithmetic mean roughness (Ra) of less than 0.08 m. The roughness (Ra) of the fifth surface (40Fa) is preferably 0.05 m or less. The roughness (Ra) of the fifth surface (40Fa) is more preferably 0.03 m or less. The arithmetic average roughness (Ra) of the upper surface (100R) of the resin 100, which forms the fifth surface (40Fa) of the resin insulating layer (40F), is less than 0.08 m. The roughness (Ra) of the upper surface (100R) of the resin 100 is preferably 0.05 m or less. The roughness (Ra) of the upper surface (100R) of the resin 100 is more preferably 0.03 m or less.

As illustrated in FIG. 3, the inorganic particles 110 can include third inorganic particles 113 that form the fifth surface (40Fa) and second inorganic particles 112 that are embedded in the resin 100. The third inorganic particles 113 each have a substantially flat exposed portion (113a). A surface (exposed surface) (113b) of the exposed portion (113a) is exposed from the upper surface (100R) of the resin 100. The fifth surface (40Fa) is formed by the upper surface (100R) of the resin 100 and the surface (113b) of the exposed portion (113a). The surface (113b) of the exposed portion (113a) and the upper surface (100R) of the resin 100 are substantially on the same plane. It is also possible that the surface (113b) of the exposed portion (113a) and the upper surface (100R) of the resin 100 do not completely match, and a gap exists between the two. A size of the gap (distance between the two) is 5 m or less. The size of the gap is preferably 3 m or less.

The inorganic particles 110 may include first inorganic particles 111, second inorganic particles 112, and third inorganic particles 113.

As illustrated in FIG. 1, the conductor layer (50F) is formed on the fifth surface (40Fa) of the resin insulating layer (40F). The conductor layer (50F) is mainly formed of copper. As illustrated in FIGS. 2 and 3, the conductor layer (50F) includes conductor circuits (52F, 54F). The conductor layer (50F) is formed of a seed layer (50Fa) and an electrolytic plating layer (50Fb) on the seed layer (50Fa).

As illustrated in FIG. 1, the via conductors (35F) are formed in openings that penetrate the resin insulating layer (40F). The via conductors (35F) connect the adjacent conductor layers (30F, 50F). The via conductors (35F) are mainly formed of copper.

The resin insulating layer (60F) is formed on the conductor layer (50F) and the fifth surface (40Fa) of the resin insulating layer (40F). The resin insulating layer (60F) has a seventh surface (60Fa) and an eighth surface (60Fb) on the opposite side with respect to the seventh surface (60Fa). The eighth surface (60Fb) is closer to the first surface (10a) than the seventh surface (60Fa). As illustrated in FIGS. 2 and 3, the resin insulating layer (60F) is formed of a resin 100 and a large number of inorganic particles 110 dispersed in the resin 100. The resin insulating layer (60F) has the same inorganic particles 110 as the inorganic particles 110 forming the resin insulating layer (40F).

As illustrated in FIG. 1, the conductor layer (70F) is formed on the seventh surface (60Fa) of the resin insulating layer (60F). The conductor layer (70F) is mainly formed of copper. The conductor layer (70F) is an uppermost conductor layer. The conductor layer (70F) has electrodes (72F) for mounting an electronic component. The first through-hole conductors 16 are respectively positioned directly below the electrodes (72F). In another example, it is also possible that some or most of the first through-hole conductors 16 are respectively positioned directly below the electrodes (72F).

The solder resist layer (80F) having openings for exposing the electrodes (72F) is formed on the conductor layer (70F) and the seventh surface (60Fa) of the resin insulating layer (60F). The solder resist layer (80F) is formed of a photocurable resin. The bonding members (90F) are formed on the electrodes (72F). The bonding members (90F) are connected to the electrodes (72F). The bonding members (90F) are formed of solder or plating. An electronic component is mounted on the bonding members (90F).

The second build-up part (20B) is formed on the tenth surface (4b) of the core substrate 4. The second build-up part (20B) has multiple conductor layers (30B, 50B, 70B) and multiple resin insulating layers (40B, 60B). The conductor layers (30B, 50B, 70B) and the resin insulating layers (40B, 60B) are alternately laminated. The second build-up part (20B) has via conductors (35B) that connect the conductor layers (30B, 50B) and via conductors (55B) that connect the conductor layers (50B, 70B). The first build-up part (20F) and the second build-up part (20B) are similar. The conductor layers (30B, 50B, 70B) are similar to the conductor layers (30F, 50F, 70F). The resin insulating layers (40B, 60B) are similar to the resin insulating layers (40F, 60F). The solder resist layer (80B) is formed on the second build-up part (20B). The solder resist layer (80B) and the solder resist layer (80F) are similar.

### Method for Manufacturing Wiring Substrate

The resin substrate 10 with the opening 11 and the glass substrate 12 are prepared. The glass substrate 12 has the multiple first through-hole conductors 16. The resin substrate 10 has the multiple second through-hole conductors 18. The density of the first through-hole conductors 16 is greater than the density of the second through-hole conductors 18. The glass substrate 12 is accommodated in the opening 11. The glass substrate 12 is fixed to the resin substrate 10 by the filling resin 14. The core substrate 4 having the ninth surface (4a) and the tenth surface (4b) is formed. The first build-up part (20F) and the second build-up part (20B) are formed on the core substrate 4. The first build-up part (20F) and the second build-up part (20B) are formed using similar methods. The method for forming the first build-up part (20F) is described below.

The conductor layer (30F) is formed on the ninth surface (4a) of the core substrate 4. The conductor layer (30F) is connected to the upper ends of the first through-hole conductors 16 and the upper ends of the second through-hole conductors 18. In a modified example, the conductor layer (30F), the first through-hole conductors 16, and the second through-hole conductors 18 may be formed at the same time.

The resin insulating layer (40F) is formed on the conductor layer (30F) and the ninth surface (4a). The fifth surface (40Fa) of the resin insulating layer (40F) is cleaned. The cleaning of the fifth surface (40Fa) is performed by sputtering using argon gas (argon sputtering). By the cleaning, about 20 nm of the resin 100 that forms the resin insulating layer (40F) is removed. By the cleaning, the resin 100 is selectively removed. The resin 100 is reduced in thickness. Some of the inorganic particles 110 (second inorganic particles 112) are partially exposed from the upper surface (100R) of the resin 100 by the cleaning. By exposing some of the second inorganic particles 112 embedded in the resin 100 from the upper surface (100R) of the resin 100, the first inorganic particles 111 are obtained. The first inorganic particles 111 are formed from the second inorganic particles 112. The resin insulating layer (40F) containing the first inorganic particles 111 and the second inorganic particles 112 is formed. After that, the embodiment can treat the fifth surface (40Fa) of the resin insulating layer (40F) with plasma. For example, the fifth surface (40Fa) of the resin insulating layer (40F) is treated with plasma of a gas containing tetrafluoromethane. The third inorganic particles 113 are formed from the first inorganic particles 111. All of the first inorganic particles 111 change to the third inorganic particles 113. A resin insulating layer (40F) containing the second inorganic particles 112 and the third inorganic particles 113 is formed. Alternatively, some of the first inorganic particles 111 change to the third inorganic particles 113. A resin insulating layer (40F) containing the first inorganic particles 111, the second inorganic particles 112, and the third inorganic particles 113 is formed.

The first inorganic particles 111 and the second inorganic particles 112 have substantially spherical shapes. The third inorganic particles 113 have substantially truncated spherical shapes. The third inorganic particles 113 have substantially flat surfaces. The substantially flat surfaces of the third inorganic particles 113 are third flat surfaces. The third flat surfaces form the fifth surface (40Fa).

The conductor layer (50F) is formed on the fifth surface (40Fa) of the resin insulating layer (40F). The via conductors (35F) are formed at the same time as the conductor layer (50F). The via conductors (35F) connect the conductor layer (30F) and the conductor layer (50F). The resin insulating layer (60F) is formed on the conductor layer (50F) and the fifth surface (40Fa). The resin insulating layer (60F) is formed using a similar method to the resin insulating layer (40F). The conductor layer (70F) is formed on the seventh surface (60Fa) of the resin insulating layer (60F). The via conductors (55F) are formed at the same time as the conductor layer (70F). The via conductors (55F) connect the conductor layer (50F) and the conductor layer (70F). The first build-up part (20F) is formed. Using a method similar to the first build-up part (20F), the second build-up part (20B) is formed. The solder resist layer (80F) and the bonding members (90F) are formed on the first build-up part (20F). The solder resist layer (80B) is formed on the second build-up part (20B). The wiring substrate 2 is obtained. The resin insulating layers are each formed of similar resin 100 and inorganic particles 110 to the resin insulating layer (40F).

In the embodiment, the density of the first through-hole conductors 16 is greater than the density of the second through-hole conductors 18. Therefore, the thermal expansion coefficient of the glass substrate 12 of the embodiment is greater than that of glass. The embodiment can reduce the difference in thermal expansion coefficient between the glass substrate 12 and the resin substrate 10. Since the resin substrate 10 has the second through-hole conductors 18, the embodiment can reduce the number of the first through-hole conductors 16 in the glass substrate 12. The embodiment can reduce the size of the glass substrate 12. The embodiment can reduce the size of the core substrate 4. The embodiment can reduce the warping of the wiring substrate 2.

The electrodes (72F) are all positioned directly above the first through-hole conductors 16. The first through-hole conductors 16 and the electrodes (72F) are connected via shortest paths.

Japanese Patent Application Laid-Open Publication No. 2014-127701 describes a wiring board having a core layer that includes a resin plate with a cavity and a glass plate in the cavity.

The core layer in Japanese Patent Application Laid-Open Publication No. 2014-127701 is formed of a glass plate and a resin plate. Due to a difference in thermal expansion coefficients between the two, it is thought that the core layer is likely to warp at a boundary between the glass plate and the resin plate.

A wiring substrate according to an embodiment of the present invention includes a core substrate and a build-up part. The core substrate includes a resin substrate that has a first surface, a second surface on the opposite side with respect to the first surface, and an opening extending from the first surface to the second surface; a glass substrate that is arranged in the opening, and has a third surface that forms a substantially common surface with the first surface, and a fourth surface on the opposite side with respect to the third surface; and a filling resin that fills a gap between the resin substrate and the glass substrate. The build-up part is formed on the core substrate, and has multiple conductor layers and multiple resin insulating layers. The conductor layers and the resin insulating layers are alternately laminated. The glass substrate has multiple first through-hole conductors extending from the third surface to the fourth surface. The resin substrate has multiple second through-hole conductors extending from the first surface to the second surface. A main material of the first through-hole conductors and the second through-hole conductors is copper. A density of the first through-hole conductors is greater than a density of the second through-hole conductors. The density of the first through-hole conductors is the number of the first through-hole conductors per unit area of the third surface. The density of the second through-hole conductors is the number of the second through-hole conductors per unit area of the first surface.

Copper has a greater thermal expansion coefficient than glass. A glass substrate forming a wiring substrate according to an embodiment of the present invention has the first through-hole conductors. Therefore, the glass substrate of the embodiment has a greater thermal expansion coefficient than glass. Additionally, the density of the first through-hole conductors is greater than the density of the second through-hole conductors. Therefore, the embodiment can reduce the difference in thermal expansion coefficients between the glass substrate and the resin substrate. Since the resin substrate has the second through-hole conductors, the embodiment can reduce the number of the first through-hole conductors. The embodiment can reduce the size of the glass substrate. The embodiment can reduce the size of the core substrate. The embodiment can reduce the warping of the wiring substrate.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a core substrate comprising a resin substrate having an opening, a glass substrate positioned in the opening of the resin substate, and a filling resin filling a gap between the resin substrate and the glass substrate; and
a build-up part formed on the core substrate and comprising a plurality of conductor layers and a plurality of resin insulating layers such that the conductor layers and the resin insulating layers are alternately laminated,
wherein the glass substrate of the core substrate has a plurality of first through-hole conductors comprising a main material comprising copper, the resin substrate of the core substrate has a plurality of second through-hole conductors comprising a main material comprising copper, and the first through-hole conductors and the second through-hole conductors are formed in the glass substrate and the resin substrate respectively such that a density of the first through-hole conductors is greater than a density of the second through-hole conductors, where the density of the first through-hole conductors is a number of the first through-hole conductors per unit area of a surface of the glass substrate, and the density of the second through-hole conductors is a number of the second through-hole conductors per unit area of a surface of the resin substrate.

2. The wiring substrate according to claim 1, wherein the first through-hole conductors and the second through-hole conductors are formed in the glass substrate and the resin substrate respectively such that a minimum spacing between adjacent first through-hole conductors is smaller than a minimum spacing between adjacent second through-hole conductors.

3. The wiring substrate according to claim 1, wherein the first through-hole conductors and the second through-hole conductors are formed in the glass substrate and the resin substrate respectively such that a maximum spacing between adjacent first through-hole conductors is smaller than a maximum spacing between adjacent second through-hole conductors.

4. The wiring substrate according to claim 1, wherein the first through-hole conductors and the second through-hole conductors are formed in the glass substrate and the resin substrate respectively such that a maximum spacing between adjacent first through-hole conductors is smaller than a minimum spacing between adjacent second through-hole conductors.

5. The wiring substrate according to claim 1, wherein the plurality of conductor layers in the build-up part includes an uppermost conductor layer including a plurality of electrodes configured to mount an electronic component such that the plurality of first through-hole conductors includes a plurality of through-hole conductors positioned directly below the plurality of electrodes.

6. The wiring substrate according to claim 1, wherein the plurality of resin insulating layers in the build-up part includes resin and inorganic particles including first particles and second particles such that the first particles are partially embedded in the resin and the second inorganic particles are embedded in the resin, each of the first particles has a first portion protruding from the resin and a second portion embedded in the resin, and each of the resin insulating layers has a surface including a surface of the resin and exposed surfaces of the first portions of the first particles.

7. The wiring substrate according to claim 6, wherein the plurality of resin insulating layers in the build-up part is formed such that a ratio of a volume of the first portions of the first particles to a volume of the first particles is larger than 0 and less than or equal to 0.4.

8. The wiring substrate according to claim 5, wherein the plurality of conductor layers in the build-up part is formed such that the first through-hole conductors formed in the glass substrate are positioned directly below the electrodes in the uppermost conductor layer, respectively.

9. The wiring substrate according to claim 1, wherein the plurality of resin insulating layers in the build-up part includes resin and inorganic particles including particles embedded in the resin having substantially spherical shapes, and particles having substantially truncated spherical shapes and having substantially flat surfaces such that each of the resin insulating layers has a surface including the flat surfaces.

10. The wiring substrate according to claim 2, wherein the first through-hole conductors and the second through-hole conductors are formed in the glass substrate and the resin substrate respectively such that a maximum spacing between adjacent first through-hole conductors is smaller than a maximum spacing between adjacent second through-hole conductors.

11. The wiring substrate according to claim 2, wherein the first through-hole conductors and the second through-hole conductors are formed in the glass substrate and the resin substrate respectively such that a maximum spacing between adjacent first through-hole conductors is smaller than a minimum spacing between adjacent second through-hole conductors.

12. The wiring substrate according to claim 2, wherein the plurality of conductor layers in the build-up part includes an uppermost conductor layer including a plurality of electrodes configured to mount an electronic component such that the plurality of first through-hole conductors includes a plurality of through-hole conductors positioned directly below the plurality of electrodes.

13. The wiring substrate according to claim 2, wherein the plurality of resin insulating layers in the build-up part includes resin and inorganic particles including first particles and second particles such that the first particles are partially embedded in the resin and the second inorganic particles are embedded in the resin, each of the first particles has a first portion protruding from the resin and a second portion embedded in the resin, and each of the resin insulating layers has a surface including a surface of the resin and exposed surfaces of the first portions of the first particles.

14. The wiring substrate according to claim 13, wherein the plurality of resin insulating layers in the build-up part is formed such that a ratio of a volume of the first portions of the first particles to a volume of the first particles is larger than 0 and less than or equal to 0.4.

15. The wiring substrate according to claim 12, wherein the plurality of conductor layers in the build-up part is formed such that the first through-hole conductors formed in the glass substrate are positioned directly below the electrodes in the uppermost conductor layer, respectively.

16. The wiring substrate according to claim 2, wherein the plurality of resin insulating layers in the build-up part includes resin and inorganic particles including particles embedded in the resin having substantially spherical shapes, and particles having substantially truncated spherical shapes and having substantially flat surfaces such that each of the resin insulating layers has a surface including the flat surfaces.

17. The wiring substrate according to claim 3, wherein the first through-hole conductors and the second through-hole conductors are formed in the glass substrate and the resin substrate respectively such that a maximum spacing between adjacent first through-hole conductors is smaller than a minimum spacing between adjacent second through-hole conductors.

18. The wiring substrate according to claim 3, wherein the plurality of conductor layers in the build-up part includes an uppermost conductor layer including a plurality of electrodes configured to mount an electronic component such that the plurality of first through-hole conductors includes a plurality of through-hole conductors positioned directly below the plurality of electrodes.

19. The wiring substrate according to claim 3, wherein the plurality of resin insulating layers in the build-up part includes resin and inorganic particles including first particles and second particles such that the first particles are partially embedded in the resin and the second inorganic particles are embedded in the resin, each of the first particles has a first portion protruding from the resin and a second portion embedded in the resin, and each of the resin insulating layers has a surface including a surface of the resin and exposed surfaces of the first portions of the first particles.

20. The wiring substrate according to claim 19, wherein the plurality of resin insulating layers in the build-up part is formed such that a ratio of a volume of the first portions of the first particles to a volume of the first particles is larger than 0 and less than or equal to 0.4.
